(19) United States
(12) Patent Application Publication
(10) Pub. No.: US 2026/0293164 A1
(43) Pub. Date: Sep. 24, 2026

(54) STRUCTURE COMPRISING AN ULTRATHIN IONIC DIELECTRIC LAYER AND ITS MANUFACTURING METHOD

(71) Applicant: COMMISSARIAT A L'ENERGIE ATOMIQUE ET AUX ENERGIES ALTERNATIVES, Paris (FR)

(72) Inventors: Messaoud BEDJAOUI, Grenoble Cedex 09 (FR); Sami OUKASSI, Grenoble Cedex 09 (FR); Sylvain POULET, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/478,413

(22) PCT Filed: Apr. 30, 2024
(86) PCT No.: PCT/FR2024/050566

§ 371 Date: Oct. 24, 2025

(30) Foreign Application Priority Data
May 2, 2023 (FR) FR2304384

(51) Int. Cl. H10D 1/00; H10D 1/68

(52) U.S. Cl. CPC H10D 1/041; H10D 1/692

(57) ABSTRACT

A structure is provided that includes a substrate covered by a first electrode, an ionic dielectric layer and a second electrode. The ionic dielectric layer includes a first part comprising a matrix based on an ionic conductor, into which a dopant is incorporated and a second part comprising an oxide of the dopant or comprising the matrix based on the ionic conductor into which the dopant is incorporated. The atomic concentration of dopant in the second part of the ionic dielectric layer is greater than the atomic concentration of dopant in the first part of the ionic dielectric layer. A method is also provided for manufacturing the above structure and to an ionic dielectric layer as defined above. The above structure can be used for micro- and nano-electronic devices, high-density capacitors of the MIM type, and synaptic transistors.

### TECHNICAL FIELD

The invention relates to the field of micro- and nano-structures for micro- and nano-electronic devices.

More specifically, the invention relates to a structure comprising a stack of an ultrathin ionic dielectric layer-used as an electrolyte-nested between two electrodes as well as to its manufacturing method.

The object of the invention is also an ionic dielectric layer.

The invention has a use in particular in the manufacturing of high-density capacitors, for example of the MIM (for Metal-Insulator-Metal) type or the manufacturing of synaptic transistors for energy storage devices.

### PRIOR ART

The advent of connected and smart objects is currently the subject of research and in particular research on highly advanced and increasingly complex micro- and nano-electronic devices.

Besides the developments related to the architecture and to the “design” of the micro- and nano-electronic components allowing to satisfy highly advanced technological criteria and performance, the development of new materials plays a key role in this research.

In the wake of this, the miniaturization of energy storage devices has been made possible by the development of three-dimensional architectures, allowing to increase their energy volume density in particular by increasing their specific surface area. Thus, the development of new dielectric layers having highly advanced ionic properties opens up a new horizon for the use of capacitors, such as capacitors of the MIM type-that is to say a dielectric layer nested between two electrodes.

Furthermore, the nano-ionic transistors using lithium-based electrolytes are considered to be promising synaptic devices for the construction of artificial neural networks for neuromorphic computing. However, the synaptic performance of these transistors is weakened in particular due to the low ionic conductivity that the electrolytes implemented in these transistors have.

The goal of optimizing the performance of micro- and nano-electronic structures thus results in the introduction, in these structures, of new extremely thin ionic dielectric layers, highly conformable and having improved ionic conductivity.

Generally, such layers are deposited by atomic layer deposition (or ALD), allowing successive depositions of extremely thin and conformable layers, that is to say perfectly conforming to the surface of the substrate which is intended to support a stack of these layers. For example, in the application EP 3570307-A1, a structure of the MOIM type—that is to say a substrate covered by a stack comprising a first electrode, a layer of oxide, an ionic dielectric layer and a second electrode—was proposed, wherein the ionic dielectric layer can be made of LiPON, LiAlF₄, LiNbO₃ and the electrodes can be made of a metal such as titanium, tantalum or cobalt or made of a metal nitride such as titanium nitride. The layers are deposited by ALD.

As for the U.S. Pat. No. 10,032,569-B2, it proposes the manufacturing of a capacitor of the MIM type in “AAO” (for “Anodic Aluminum Oxide”) structures. In this patent, the nature of the ionic dielectric layer can be chosen from a broad list of materials, including for example LiPON, LiAlO₂ and Al₂O₃, while the electrodes can be made of a metal and/or metal nitride such as aluminum, copper, tungsten, tungsten nitride and titanium nitride.

However, during the growth of a metal electrode on an ionic dielectric layer, the ionic elements of this layer are capable of interacting with elements of the electrode, slowing down or even inhibiting the growth of this electrode.

In addition, electrodes made of a nitrided metal are generally obtained from reactive species comprising a halogen and more particularly chlorine or iodine. However, these halogens are highly susceptible to migrate into the underlying ionic dielectric layer, thus affecting the electronic insulation properties of the latter.

Given the above, the inventors have set the goal of overcoming the disadvantages of the prior art, in particular by proposing a structure comprising an ionic dielectric layer nested between two electrodes, the ionic dielectric layer further having a greater ionic conductivity than the ionic dielectric layers known from the prior art and allowing the growth of an electrode on its surface, while preserving its electronic insulation properties.

### DISCLOSURE OF THE INVENTION

The invention aims precisely to provide such a structure.

The object of the invention is therefore, firstly, a structure that comprises a substrate successively covered by a first electrode, an ionic dielectric layer and a second electrode, characterized in that the ionic dielectric layer comprises:
a first part, in contact with the first electrode, comprising a matrix based on an ionic conductor into which a dopant is incorporated;
a second part, in contact with the second electrode, comprising an oxide of the dopant or comprising the matrix based on the ionic conductor into which the dopant is incorporated;
   the atomic concentration of dopant in the second part of the ionic dielectric layer being greater than the atomic concentration of dopant in the first part of the ionic dielectric layer.

The invention fundamentally differs from the prior art by the use of an ionic dielectric layer having two parts.

The second part of the ionic dielectric layer allows not only to improve the overall ionic conductivity but also to have a surface promoting the growth of the upper electrode layer (that is to say the second electrode) without altering the electrical operation of such a structure.

Such an ionic dielectric layer has good performance and can be easily integrated into the construction and manufacturing of MIM microstructures and nanostructures.

It should be noted that the matrix of the ionic dielectric layer can comprise one or more dopants and that this ionic dielectric layer can comprise one or more first parts and one or more second parts, in the form of an alternation of first parts and second parts, a second part being in contact with the second electrode.

Dopant is understood as any compound that can be incorporated into the matrix of the ionic dielectric layer allowing an increase in the ionic conductivity of this layer.

Preferably, the dopant is a chemical element that is not part of the composition of the ionic dielectric layer, that is to say that it can be likened to an additive of this ionic dielectric layer.

The dopant is advantageously present in the matrix of the ionic dielectric layer according to a gradient, that is to say that the second part of this ionic dielectric layer is rich in dopant relative to the first part of this same layer which, in turn, is rich in ionic conductor. In other words, the atomic concentration of dopant increases in an increasing and progressive manner in the ionic dielectric layer from the first electrode towards the second electrode, or even all the way to the second electrode.

This gradient allows to modify the surface of the ionic dielectric layer intended to be in contact with the second electrode. This modification allows to make this surface easily functionalizable and, consequently, allows to promote the growth of the second electrode.

Above and below, “growth” means the fact that the second electrode can be deposited and grow on the surface of an underlying ionic dielectric layer, so as to have a homogeneous desired thickness over this entire surface. The second electrode is continuous.

Moreover, the second part of the ionic dielectric layer, rich in dopant and in contact with the second electrode, also acts as a “barrier”, that is to say that it prevents or, at the very least, minimizes the possible diffusion or migration of the chemical elements from the second electrode toward the ionic dielectric layer, these elements not being desirable in the ionic dielectric layer in particular because they are susceptible to affect the electronic insulation properties of this layer. Such elements can be chlorine or iodine for example.

As indicated above, according to a first alternative embodiment, the second part of the ionic dielectric layer is an oxide of the dopant. For example if the dopant is silicon, the second part of the ionic dielectric layer is made of silicon oxide.

According to a second alternative embodiment, the second part of the ionic dielectric layer comprises the matrix based on the ionic conductor into which the dopant is incorporated. According to this alternative embodiment, it is preferred for the second part of the ionic dielectric layer to have an atomic concentration of dopant ranging from 50% to 97%, preferably ranging from 90% to 97% while the first part advantageously has an atomic concentration of dopant ranging from 3% to 50%, preferably ranging from 3% to 10%.

Above and below, it is specified that the atomic concentration of dopant corresponds, in percentage, to the ratio of the number of atoms of this dopant present in the matrix of the ionic dielectric layer to the total number of atoms of the dopant added to the number of atoms of the ionic conductor. For example, for an ionic dielectric layer of the LiPON type doped with silicon, the atomic concentration of dopant, in percentage, is defined by the following ratio R:

$$R = 100 \times \{ d / \{ Li + d \} \}$$

with d the number of atoms of dopant, here silicon,
Li the number of atoms of the ionic conductor, here lithium.

Moreover, above and below, the expressions “from . . . to . . . ” and “between . . . and . . . ” are equivalent and intend to mean that the limits are included.

In the context of the invention, the ionic dielectric layer is an ultrathin layer and advantageously has a total thickness of between 3 nm and 100 nm, preferably between 5 nm and 20 nm and, even better, equal to 10 nm.

Furthermore, it is preferred for the second part of the ionic dielectric layer to represent from 5% to 20% of the total thickness of the ionic dielectric layer and, even better, from 5% to 10%.

According to the invention, the dopant of the ionic dielectric layer can be chosen from silicon, aluminum, titanium, tantalum, zirconium and lanthanum, preference being given to silicon.

Furthermore, above and below, “ionic conductor” means any element capable of providing cations with a degree of ionic mobility sufficient to confer onto the ionic dielectric layer, in a first step, an ionic conductivity at least equal to 10⁻⁷ S/cm, such cations can be cations of lithium, magnesium, sodium, potassium, copper, silver, aluminum or zinc.

For example, when the ionic conductor is chosen so as to provide lithium cations, the ionic dielectric layer can be made of a solid electrolyte based on sulfur compounds (like the compounds called LGPS or LPS), an oxide having a structure of the garnet type (such as an oxide of lithium lanthanum zirconium or called LLZO), an ionic conductor of the NaSiCON type or an oxynitride comprising lithium (such as LiPO, LiPON, LiAlO₂ or LATP).

Another example can be when the ionic conductor is chosen so as to provide magnesium cations. In this case, the ionic dielectric layer can be made of a magnesium phosphate.

According to the invention, the ionic dielectric layer is advantageously made of a material chosen from lithium phosphorus oxynitride (more simply noted as LiPON), lithium metasilicate and magnesium phosphate, preference being given however to lithium phosphorus oxynitride.

Thus, by combining the ionic conductor and the dopant, the ionic dielectric layer of the structure according to the invention advantageously has an ionic conductivity at least equal to 10⁻⁶ S·cm⁻¹ and, even better, at least equal to 10⁻⁵ S·cm⁻¹.

As mentioned above, the structure according to the invention comprises a substrate successively covered by a first electrode, an ionic dielectric layer and a second electrode.

Typically, the first and the second electrode are made of a material having a low electrical resistivity, for example less than 200μΩcm. The first electrode and the second electrode, identical or different, are preferably made of a metal such as titanium, platinum, tungsten, ruthenium, or molybdenum or made of a metal nitride such as titanium nitride, tantalum nitride, tungsten nitride or molybdenum nitride, preference being given however to titanium nitride (noted as TIN).

The first electrode and the second electrode generally have a thickness of less than 20 nm, for example equal to 10 nm.

Furthermore, the substrate of the structure according to the invention can have a flat surface—that is to say in two dimensions—or a microstructured surface—that is to say in three dimensions.

Above and below, “microstructured surface” means a surface comprising pores or vias, for example having an elongated shape, which allows in particular to increase the specific surface area of the substrate—that is to say the surface area of the substrate intended to be successively covered by the first electrode, the ionic dielectric layer and the second electrode—relative to a flat surface.

Thus, a microstructured surface can have a more or less large aspect ratio, this aspect ratio corresponding to the ratio of the longitudinal dimension to the transverse dimension of the pores or of the vias. Thus, the higher the aspect ratio, the greater the specific surface area of the substrate. For example, an aspect ratio greater than 20 can be contemplated.

The substrate can also comprise microelectronic components.

The substrate can be made of silicon, metal nitride or a material based on metal oxide such as alumina, or any other suitable material.

The structure as described above can in particular be prepared by a method which comprises at least the following successive steps:
a) depositing the first electrode on the substrate; then
b) depositing the ionic dielectric layer; then
c) depositing the second electrode;
   the method being characterized in that step b) is carried out by ALD according to the following substeps:
i) forming the first part of the ionic dielectric layer by repeating several times, for example between 40 and 180 times, the following first cycle of substeps i1) and i2):
   i1) introducing and alternately circulating precursors of the ionic conductor on the first electrode; then
   i2) introducing and alternately circulating precursors of the dopant on the first electrode;
ii) forming the second part of the ionic dielectric layer by repeating several times, for example between 5 and 30 times, a substep consisting in introducing and circulating, alternately, precursors of the oxide of the dopant on the first electrode, or forming the second part of the ionic dielectric layer by repeating several times, for example between 5 and 30 times, the following second cycle of substeps ii1) and ii2):
   ii1) introducing and alternately circulating the precursors of the ionic conductor on the first electrode; then
   ii2) introducing and alternately circulating the precursors of the dopant on the first electrode.

The technique of deposition by ALD under vacuum (from several mTorr to several Torr; or between approximately 0.1 Pa and several hundred Pa, for example 300 Pa) allows in particular to obtain highly conformable layers having a very high purity and very small thickness.

The sequence of steps a), b) and c) is carried out without breaking the vacuum, which allows to avoid any formation of layers of oxides between the first electrode and the ionic dielectric layer and/or between the ionic dielectric layer and the second electrode, these layers of oxides not being desirable in such a structure since they could alter its correct electrical operation.

The principle of deposition by ALD lies in introducing at least two reactive species, called “precursors”, into an ALD chamber and then circulating them alternately on the surface of a material.

The deposition by ALD of step b) can be implemented at a temperature between 200° C. and 420° C., for example at 330° C. It allows in particular to control the distribution of the dopant during its incorporation into the matrix of the ionic dielectric layer, so as to obtain a gradient.

To do this, substep i1) is, preferably, repeated at least 10 times before carrying out substep i2). If substeps ii1) and ii2) are carried out, then ii2) is repeated, preferably, at least 10 times during the implementation of the second cycle.

Indeed, the number of repetitions of the first cycle and/or of the second cycle is directly related to the desired thickness of the first part of the ionic dielectric layer and/or of the second part of the ionic dielectric layer.

For example, to obtain the first part of the ionic dielectric layer with a thickness of 9 nm, the first cycle of substep i) is typically repeated between 80 and 90 times, for example 88 times, and to obtain a thickness of 1 nm for the second part of this same layer, the second cycle of substep ii) can be repeated between 10 and 15 times, for example 12 times.

Alternatively for example, it is possible to repeat substeps i) and ii) of step b) cyclically to form an alternation of first parts and second parts in the ionic dielectric layer, a second part being in contact with the second electrode. For example, it is possible to carry out step b) so as to obtain a first part of the ionic dielectric layer with a thickness of 2 nm and a second part of this same layer with a thickness of 0.5 nm, then repeat the steps until an ionic dielectric layer is obtained, preferably having a thickness of 10 nm and comprising an alternation of first and second parts, with it being understood that one of the second parts must be in contact with the second electrode.

Preferably, the introduction of each of these precursors is followed by a time, called waiting time, before carrying out a purge thereof.

The waiting time represents the residence time of the precursors on the surface of the substrate or, if applicable, on the surface of the underlying layer or electrode. It is directly proportional to the value of the aspect ratio of the substrate. The waiting time allows to make the precursors diffuse and react in an optimal manner, in particular in the complex structures comprising for example a microstructured surface with a high aspect ratio.

Typically, during substeps i1), i2), ii1) and ii2), after the introduction and the circulation of each precursor of the ionic conductor and/or after the introduction and the circulation of each precursor of the dopant, a waiting time having a duration of between 15 seconds and 100 seconds, preferably between 20 seconds and 50 seconds and, even better, equal to 30 seconds, is observed before carrying out a purge. The purge can be carried out for a duration at least equal to 40 seconds, to eliminate the excess precursors and the possible undesired byproducts, obtained during a reaction between the precursors.

Furthermore, according to the invention, the precursors of the ionic conductor are chosen from one of the following pairs of precursors: lithium hexamethyldisilazane (noted as LiHMDS) coupled with diethyl phosphoramidate (noted as DEPA), lithium tert-butylate (noted as LiOtBu) coupled with diethyl phosphoramidate and lithium tert-butylate coupled with trimethyl phosphite (noted as TMPO) and/or the precursors of the dopant or the precursors of the oxide of the dopant are selected from one of the following pairs of precursors: tris(dimethylamino) silane (noted as 3DMAS) coupled with ozone (noted as O₃) or water, bis(dimethylamino)dimethylsilane (noted as BDEAS) coupled with ozone or water.

Indeed, the precursors of the ionic conductor and of the dopant or where applicable of the oxide of the dopant are chosen according to the desired nature of the ionic dielectric layer and of the dopant. The pairs of precursors mentioned above allow for example to obtain the first part of the ionic dielectric layer made of silicon-doped lithium phosphorus oxynitride (more simply noted as LiSiPON) and the second part of this same layer made of silicon oxide (SiO₂).

Alternatively, trimethylaluminum (noted as TMA) can be used as a precursor of the dopant coupled with deionized water allowing to obtain the second part of the ionic dielectric layer made of an aluminum oxide and more particularly here made of alumina.

Another alternative can be implemented by using as precursors LiOtBu coupled with tetraethyl orthosilicate (noted as TEOS), in which case the ionic dielectric layer is made of lithium metasilicate.

Another alternative can also be when the ionic conductor is chosen so as to provide magnesium cations. In this case, by using as precursors bis(methylcyclopentadienyl) magnesium (noted as Mg(EtCp)₂) coupled with tris(dimethylamino)phosphine (noted as TDMAP), water and oxygen, an ionic dielectric layer of the magnesium phosphate type can be obtained.

By thus implementing step b) of the method of the invention, the ionic dielectric layer is obtained, from a macroscopic point of view, in a single step and comprises, from a microscopic point of view, two distinct parts, the second part of which—in contact with the second electrode—is rich in dopant, unlike the first part which is rich in ionic conductor.

Preferably, the substeps of step b) are carried out at the same temperature.

Moreover, steps a) and c) of the method are typically implemented by a deposition by ALD and, preferably, at a temperature between 200° C. and 450° C., for example equal to 400° C., while observing the same waiting and purge time as those set in step b).

In addition, steps a) and c) are preferably carried out by depositing via ALD a metal halide and/or an organometallic, the metal halide preferably comprising chlorine, iodine or bromine.

During steps a) and c), the metal halide and/or the organometallic are generally coupled with ammonia.

In the context of the invention, the halide is generally preferred to the organometallic in particular because it has a high thermal stability, a high saturation vapor pressure and a high reactivity.

More particularly, the metal halide can be chosen from titanium tetrachloride, titanium iodide and titanium tetrabromide, preference being given however to titanium tetrachloride (TiCl₄).

Indeed, the halide and/or the organometallic are chosen according to the desired nature of the first and second electrode. For example, by implementing steps a) and c) with titanium tetrachloride coupled with ammonia, an electrode made of titanium nitride is obtained.

It should be noted that the second electrode can comprise a single layer or a multitude of layers, the nature and the deposition technique of which can differ from the first electrode.

Alternatively to the deposition by ALD, steps a), b) and c) can also be implemented by a plasma-enhanced ALD method (also called PEALD for Plasma-Enhanced Atomic Layer Deposition), by a spatial ALD method (also called SALD for Spatial Atomic Layer Deposition) or by an ALD method at atmospheric pressure.

Other alternatives can be implemented, in particular for steps a) and c), such as deposition techniques adapted to thin layers, like physical vapor deposition (or PVD) or like chemical vapor deposition (or CVD).

A person skilled in the art is perfectly capable of choosing the most suitable deposition method, in particular according to the surface of the substrate used (flat or microstructured).

The object of the invention is also an ionic dielectric layer comprising:
a first part comprising a matrix based on an ionic conductor, into which a dopant is incorporated;
a second part comprising an oxide of the dopant or comprising the matrix based on an ionic conductor into which a dopant is incorporated;
the atomic concentration of dopant in the second part of the ionic dielectric layer being greater than the atomic concentration of dopant in the first part of the ionic dielectric layer.

The dopant is advantageously present in the matrix of the ionic dielectric layer according to a gradient, that is to say that the second part of this ionic dielectric layer is rich in dopant relative to the first part of this same layer which, in turn, is rich in ionic conductor. In other words, the atomic concentration of dopant increases in an increasing and progressive manner in the ionic dielectric layer from the first part towards the second part.

Preferably, the dopant is a chemical element that is not part of the composition of the ionic dielectric layer, that is to say that it can be likened to an additive of this ionic dielectric layer.

Other features and advantages of the invention will be clear from the following additional description.

It goes without saying that this additional description is only given as an illustration of the object of the invention and must in no case be interpreted as a limitation of this object.

### BRIEF DESCRIPTION OF THE DRAWINGS

FIG. 1 shows a substrate 1 having a flat surface covered by a first electrode 2, a dielectric layer 3 comprising a first part 31 and a second part 32 and a second electrode 4 according to a first specific embodiment of the invention.

FIG. 2 shows a substrate 1 having a microstructured surface covered by a first electrode 2 according to another specific embodiment of the invention.

FIG. 3 shows the steps of a synthesis of deposition of an ionic dielectric layer comprising a first part and a second part, according to a specific embodiment of the invention.

FIG. 4 shows a structure comprising the substrate 1, the surface of which is covered by a stack comprising the first electrode 2 and an ionic dielectric layer 3, according to another specific embodiment (for reasons of readability, the detail of the ionic dielectric layer is not shown in this drawing).

FIG. 5 is an enlargement of a part of FIG. 4; it shows a structure comprising the substrate 1, the surface of which is covered by a stack comprising the first electrode 2, the ionic dielectric layer 3 comprising a first part 31 and a second part 32.

FIG. 6 shows a structure S1 of the MIM type comprising the substrate 1, the surface of which is covered by a stack comprising the first electrode 2, the ionic dielectric layer 3 and a second electrode 4, according to another specific embodiment (for reasons of readability, the detail of the ionic dielectric layer is not shown in this figure).

FIG. 7 shows the steps of a synthesis of deposition of an ionic dielectric layer comprising a first part and a second part, according to another specific embodiment of the invention.

It should be noted that the drawings described above are schematic representations, the relative dimensions and proportions of the substrate 1, of the first electrode 2, of the ionic dielectric layer 3 and of the second electrode 4 of which are not representative of those likely to be presented in a real situation, for reasons of readability.

### DETAILED DISCLOSURE OF SPECIFIC EMBODIMENTS

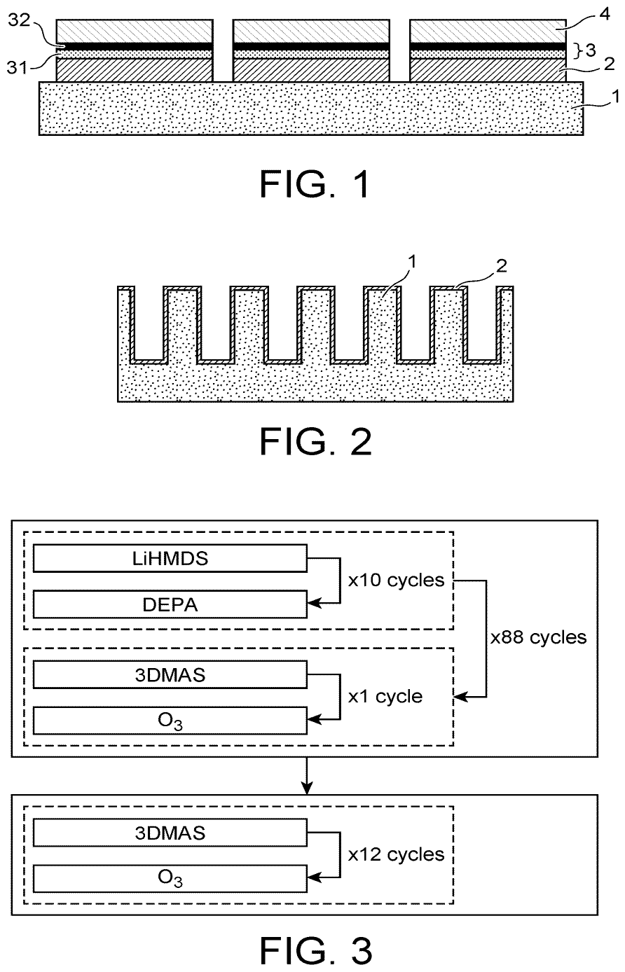

In the various examples that follow, the substrate is a microstructured substrate. However, as shown in FIG. 1, the method for manufacturing the MIM structure could be applied to a substrate 1 having a flat surface. The various elements (first electrode 2, ionic dielectric layer 3 comprising a first part 31 and a second part 32, second electrode 4) are then successively deposited on the substrate 1.

### Example 1: Manufacturing a First Structure S1

### 1.1—Deposition of the First Electrode:

A substrate 1 is placed in an ALD chamber under vacuum dedicated to depositions of electrodes.

The substrate 1 is made of silicon with an electrical insulation made of silicon oxide. It has a microstructured surface so as to confer onto it an aspect ratio greater than 20 (FIG. 2).

A deposition by ALD is implemented at a temperature of 400° C. by carrying out the cycle of following steps:
injecting TiCl₄ for an injection duration equal to 2 seconds;
circulating the TiCl₄ on the surface of the substrate 1, while observing a waiting time equal to 30 s;
purging for 40 seconds the excess TiCl₄; then
injecting ammonia (NH₃);
circulating the NH₃ on the surface of the substrate 1;
purging the excess NH₃ as well as of the possible byproducts obtained during a reaction between the TiCl₄ and the NH₃.

The duration of injection, the time of waiting and of purging the NH₃ are the same as those applied for the TiCl₄.

The above cycle is repeated 200 times.

Thus, the first electrode 2 made of TIN, having a thickness of 10 nm, is deposited homogeneously over the entire specific surface area of the substrate 1, as illustrated in FIG. 2.

### 1.2—Deposition of the Ionic Dielectric Layer:

The assembly formed by the substrate 1 and the first electrode 2 made of TIN, obtained in point 1.1 above, is moved to a second ALD chamber under vacuum, this time dedicated to the deposition of ionic dielectric layers.

The movement is carried out without passage through air—that is to say that the assembly remains under vacuum—to avoid any formation of an additional layer of oxide on the surface of the electrode 2 made of TIN.

A deposition by ALD is carried out at 330° C. according to the steps as illustrated in FIG. 3, and which correspond to:
i) forming the first part 31 of the ionic dielectric layer 3 by repeating 88 times the following cycle of substeps i1) and i2):
   i1) introducing and alternately circulating LiHMDS and DEPA on the surface of the first electrode 2 made of TIN; this substep is repeated 10 times;
   i2) introducing and alternately circulating 3DMAS and O₃ on the surface of the first electrode 2 made of TIN;
ii) forming the second part 32 of the ionic dielectric layer 3 by repeating 12 times an introduction and an alternating circulation of 3DMAS and O₃ on the surface of the first electrode 2 made of TIN.

After each introduction and circulation of the LiHMDS, DEPA, 3DMAS and O₃ compounds, a purge of each of these compounds is implemented.

The duration of injection, the waiting and purge time are the same for each of these compounds and are 2 s, 30 s and 40 s, respectively.

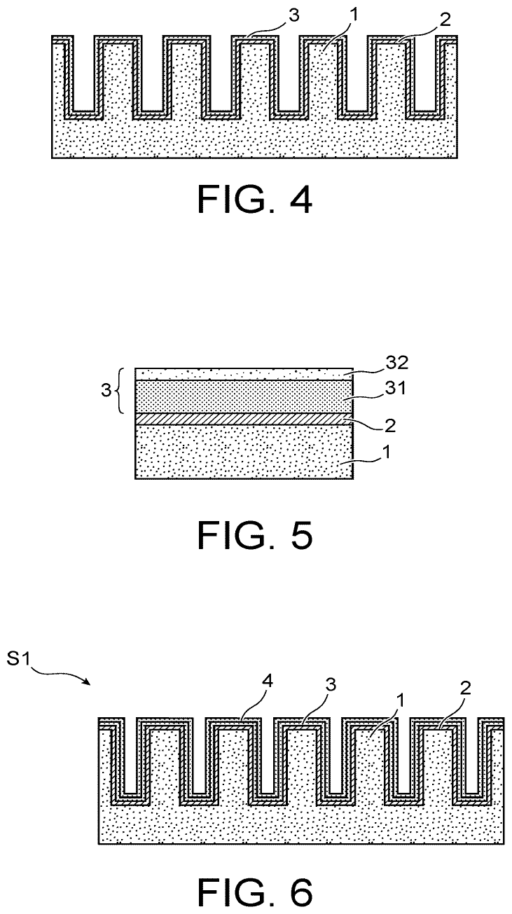

Thus, the ionic dielectric layer 3 made of LISIPON is deposited homogeneously on the surface of the first electrode 2 made of TIN, as illustrated in FIG. 4.

The layer 3 made of LiSiPON thus obtained has an ionic conductivity of approximately 10⁻⁵ S/cm, a total thickness of 10 nm and comprises, as illustrated in FIG. 5:
a first part 31 made of LiSiPON having a thickness of 9 nm and comprising an atomic concentration of silicon equal to 10% relative to the total number of lithium atoms; and
a second part 32 made of SiO₂ having a thickness of 1 nm and characterized by a very high silicon concentration.

### 1.3—Deposition of the Second Electrode:

The assembly formed by the substrate 1, the first electrode 2 made of TIN and the ionic dielectric layer 3 made of LiSiPON obtained in point 1.2 above is moved to a third ALD chamber under vacuum, dedicated to the depositions of electrodes.

The movement from the second to the third ALD chamber is here also carried out without passage through air, to avoid any formation of layers of oxide on the surface of the ionic dielectric layer 3 made of LiSiPON.

A second electrode 4 made of TIN is deposited homogeneously on the surface of the ionic dielectric layer 3 made of LiSiPON, obtained in point 1.2 above, by implementing the same cycle of steps as that described in point 1.1.

The second electrode 4 made of TiN thus deposited has a thickness of 10 nm.

A structure S1 of the MIM type is thus obtained and is shown in FIG. 6.

### Example 2: Manufacturing a Second Structure

In this example, the substrate used is made of silicon with an electrical insulation made of silicon oxide and has a microstructured surface similar to the surface of the substrate 1 used in the previous example.

Furthermore, in this example the deposition of the first electrode 2 and the deposition of the second electrode 4 are carried out in the same way as in example 1. Only the step of depositing the ionic dielectric layer is different.

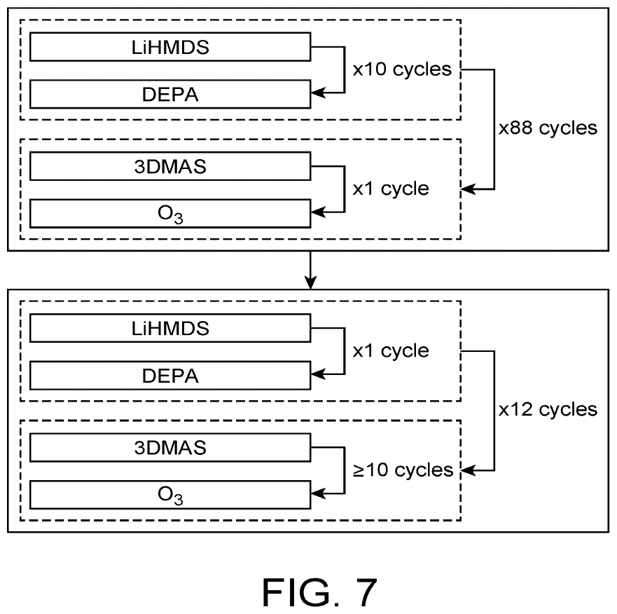

Here too, a deposition by ALD, at a temperature of 330° C., is carried out, but this time by carrying out the steps shown in FIG. 7, which correspond to:
i) forming the first part of the ionic dielectric layer by repeating 88 times the following cycle of substeps i1) and i2):
   i1) introducing and alternately circulating LiHMDS and DEPA on the surface of the first electrode 2 made of TIN; this substep is repeated 10 times;
   i2) introducing and alternately circulating 3DMAS and O₃ on the surface of the first electrode 2 made of TIN; and
ii) forming the second part of the ionic dielectric layer by repeating 12 times the following cycle of substeps ii1) and ii2):
   ii1) introducing and alternately circulating LiHMDS and DEPA on the surface of the first electrode 2 made of TIN;
   ii2) introducing and alternately circulating 3DMAS and O₃ on the surface of the first electrode 2 made of TIN; this substep is repeated 10 times.

Here also, after each introduction and circulation of the LiHMDS, DEPA, 3DMAS and O₃ compounds, a purge of each of these compounds is implemented.

The duration of injection, the waiting and purge time are the same for each of these compounds and are 2 s, 30 s and 40 s, respectively.

The ionic dielectric layer of LiSiPON thus deposited on the surface of the first electrode 2 made of TiN has an ionic conductivity of approximately 10-6 S/cm, a total thickness of 10 nm and comprises:
a first part made of LiSiPON having a thickness of 9 nm and comprising an atomic concentration of silicon equal to 10% relative to the total number of lithium atoms; and
a second part also made of LiSiPON having a thickness of 1 nm and comprising an atomic concentration of silicon equal to 90% relative to the total number of lithium atoms.

1. A structure comprising a substrate successively covered by a first electrode, an ionic dielectric layer and a second electrode, characterized in that the ionic dielectric layer comprises:
a first part, in contact with the first electrode, comprising a matrix based on an ionic conductor, into which a dopant is incorporated;
a second part, in contact with the second electrode, comprising an oxide of the dopant or comprising the matrix based on the ionic conductor into which the dopant is incorporated;
the atomic concentration of dopant in the second part of the ionic dielectric layer being greater than the atomic concentration of dopant in the first part of the ionic dielectric layer and the dopant being present in the matrix of the ionic dielectric layer according to a gradient.

2. The structure according to claim 1, wherein the dopant is a chemical element that is not part of the composition of the ionic dielectric layer.

3. The structure according to claim 1, wherein the second part of the ionic dielectric layer has an atomic concentration of dopant ranging from 50% to 97%, preferably ranging from 90% to 97%, and wherein the first part has an atomic concentration of dopant ranging from 3% to 50%, preferably ranging from 3% to 10%.

4. The structure according to claim 1, wherein the ionic dielectric layer has a total thickness of between 3 nm and 100 nm, preferably between 5 nm and 20 nm and, more preferably, equal to 10 nm.

5. The structure according to claim 4, wherein the second part of the ionic dielectric layer represents from 5% to 20% of the total thickness of the ionic dielectric layer and, more preferably, from 5% to 10%.

6. The structure according to claim 1, wherein the dopant of the ionic dielectric layer is chosen from silicon, aluminum, titanium, tantalum, zirconium, and lanthanum, preference being given to silicon.

7. The structure according to claim 1, wherein the matrix of the ionic dielectric layer is made of a material chosen from lithium phosphorus oxynitride, lithium metasilicate and magnesium phosphate, preference being given to lithium phosphorus oxynitride.

8. The structure according to claim 1, wherein the ionic dielectric layer has an ionic conductivity at least equal to 10-6 S·cm⁻¹, preferably at least equal to 10-5 S·cm⁻¹.

9. The structure according to claim 1, wherein the first electrode and the second electrode, identical or different, are made of a metal such as titanium, platinum, tungsten, ruthenium, or molybdenum or made of a metal nitride such as titanium nitride, tantalum nitride, tungsten nitride or molybdenum nitride, preference being given to titanium nitride.

10. The structure according to claim 1, wherein the substrate has a flat or microstructured surface.

11. A method for manufacturing a structure as defined according to claim 1, comprising at least the following successive steps:
a) depositing the first electrode on the substrate; then
b) depositing the ionic dielectric layer; then
c) depositing the second electrode;
the method wherein step b) is carried out by ALD according to the following substeps:
i) forming the first part of the ionic dielectric layer by repeating several times, for example between 40 and 180 times, the following first cycle of substeps i1) and i2):
i1) introducing and alternately circulating precursors of the ionic conductor on the first electrode; then
i2) introducing and alternately circulating precursors of the dopant on the first electrode;
ii) forming the second part of the ionic dielectric layer by repeating several times, for example between 5 and 30 times, a substep consisting in alternately introducing and circulating precursors of the oxide of the dopant on the first electrode, or forming the second part of the ionic dielectric layer by repeating several times, for example between 5 and 30 times, the following second cycle of substeps ii1) and ii2):
ii1) introducing and alternately circulating the precursors of the ionic conductor on the first electrode; then
ii2) introducing and alternately circulating the precursors of the dopant on the first electrode.

12. The method according to claim 11, wherein substep i1) is repeated at least 10 times before carrying out substep i2) and wherein, if substeps ii1) and ii2) are carried out, then ii2) is repeated at least 10 times during the implementation of the second cycle.

13. The method according to claim 11, wherein during substeps i1), i2), ii1) and ii2), after the introduction and the circulation of each precursor of the ionic conductor or after the introduction and the circulation of each precursor of the dopant, a waiting time having a duration of between 15 seconds and 100 seconds, preferably between 20 seconds and 50 seconds and, even better, equal to 30 seconds, is observed before carrying out a purge.

14. The method according to claim 11, wherein the precursors of the ionic conductor are chosen from one of the following pairs of precursors: lithium hexamethyldisilazane coupled with diethyl phosphoramidate, lithium tert-butylate coupled with diethyl phosphoramidate and lithium tert-butylate coupled with trimethyl phosphite and/or wherein the precursors of the dopant or the precursors of the oxide of the dopant are chosen from one of the following pairs of precursors: tris(dimethylamino)silane coupled with ozone or water, bis(dimethylamino)dimethylsilane coupled with ozone or water.

15. The method according to claim 11, wherein steps a) and c) are carried out by depositing via ALD a metal halide and/or an organometallic, the metal halide preferably comprising chlorine, iodine or bromine.

16. The method according to claim 15, wherein the metal halide is chosen from titanium tetrachloride, titanium iodide, and titanium tetrabromide, preference being given to titanium tetrachloride.

17. An ionic dielectric layer comprising:
a first part comprising a matrix based on an ionic conductor, into which a dopant is incorporated;
a second part comprising an oxide of the dopant or comprising the matrix based on the ionic conductor into which the dopant is incorporated;
the atomic concentration of dopant in the second part in the ionic dielectric layer being greater than the atomic concentration of dopant in the first part of the ionic dielectric layer and the dopant being present in the matrix of the ionic dielectric layer according to a gradient.
